(19) United States
(12) Patent Application Publication
(10) Pub. No.: US 2011/0255231 A1
(43) Pub. Date: Oct. 20, 2011

(54) PORTABLE DIGITAL DATA STORAGE DEVICE AND ANALYZING METHOD THEREOF

(75) Inventor: CHIEN-HUA SU, Hsinchu (TW)

(73) Assignee: Codetek Technology Co., LTD., Hsinchu City (TW)

(21) Appl. No.: 13/083,530

(22) Filed: Apr. 8, 2011

(30) Foreign Application Priority Data
Apr. 14, 2010 (TW) 099111672
Apr. 14, 2010 (TW) 099111676
Apr. 14, 2010 (TW) 099206739

(51) Int. Cl. H05K 7/00

(52) U.S. Cl. 361/679.26; 361/679.31; 361/679.33

(57) ABSTRACT

A portable digital data storage device is selectively in communication with an external electronic device through a communication interface. The portable digital data storage device includes a storage unit and a control unit. The storage unit has a storage space. The storage space is divided into a plurality of analyzable sections. The control unit is electrically connected with the communication interface for controlling an accessing operation of the storage unit. The control unit judges a utilization condition of the storage space according to usage statuses of respective analyzable sections, thereby acquiring analyzing information of the storage space.

### FIELD OF THE INVENTION

The present invention relates to a portable digital data storage device, and more particularly to a portable digital data storage device for quickly acquiring analyzing information of a storage space. The present invention relates to an analyzing method for analyzing the portable digital data storage device.

### BACKGROUND OF THE INVENTION

Generally, portable digital data storage devices are used for making up for the deficient of the storage space of the built-in storage devices, having backup of the data, or storing the large-sized files (e.g. multimedia file) that are not suitably transferred through the network. Consequently, the portable digital data storage devices are now gaining in popularity.

As known, most of the conventional portable digital data storage devices only support the file allocation table (FAT) series file systems. In a case that a conventional portable digital data storage device is operated in another file system, the portable digital data storage device should be connected with an external electronic device (e.g. a computer) to perform the subsequent operations.

Moreover, as the capacity of the storage unit of the portable digital data storage device is gradually increased, it is more time-consuming to analyze the utilization condition of the storage space of the portable digital data storage device. If the processing unit has inferior computing capability, the user needs to wait for a long time period to acquire the analyzing result. For efficiently realizing the utilization condition of the storage space, the portable digital data storage device should be connected to an external electronic device with high computing capability.

That is, if the user wants to realize the usable storage space and the file system format of the conventional portable digital data storage device, the portable digital data storage device should be connected to the external electronic device. The portable digital data storage device is not user-friendly.

Therefore, there is a need of providing a method for quickly acquiring associated information and analyzing the storage space of a portable digital data storage device without the need of connecting the portable digital data storage device to the external electronic device.

### SUMMARY OF THE INVENTION

Therefore, the present invention provides a portable digital data storage device. The portable digital data storage device is selectively in communication with an external electronic device through a communication interface. The portable digital data storage device includes a storage unit and a control unit. The storage unit has a storage space. The storage space is divided into a plurality of analyzable sections. The control unit is electrically connected with the communication interface for controlling an accessing operation of the storage unit. The control unit judges a utilization condition of the storage space according to usage statuses of respective analyzable sections, thereby acquiring analyzing information of the storage space.

The present invention also provides an analyzing method for analyzing a storage space of a portable digital data storage device. The analyzing method includes the following steps. Firstly, the storage space is divided into a plurality of analyzable sections. Then, a utilization condition of the storage space is judged according to usage statuses of respective analyzable sections, thereby acquiring analyzing information of the storage space.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1 is a schematic functional block diagram illustrating a portable digital data storage device in communication with an external electronic device according to an embodiment of the present invention;

FIG. 2 schematically illustrates the relationship between the storage unit and the samplers and the accumulator of the control unit; and

FIG. 3 is a flowchart illustrating an analyzing method for analyzing a storage space of a portable digital data storage device according to an embodiment of the present invention.

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

The present invention provides a portable digital data storage device and an analyzing method for analyzing the storage space of the portable digital data storage device in order to increase the convenience of acquiring associated information of the storage space. By the analyzing method, the analyzing information of the storage unit of the portable digital data storage device can be quickly acquired. The analyzing information comprises a film system format, a used storage space, a usable storage space or a volume label. As a consequence, the utilization condition of the storage space and the data storage format can be quickly realized by the user. An example of the portable digital data storage device is a non-volatile storage device such as a hard disc or a flash memory.

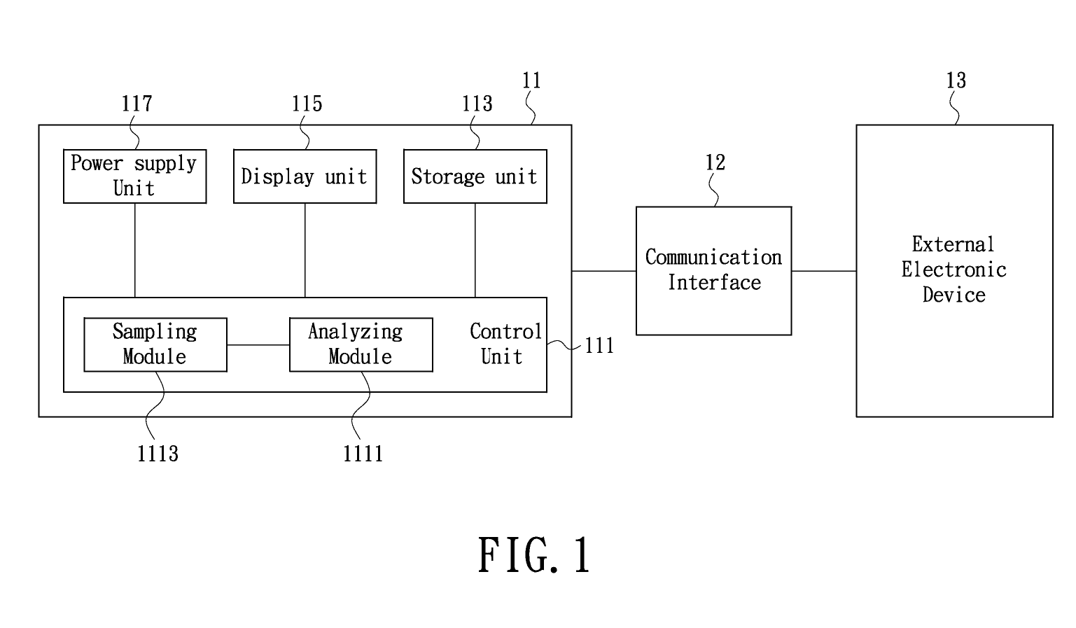

FIG. 1 is a schematic functional block diagram illustrating a portable digital data storage device in communication with an external electronic device according to an embodiment of the present invention. As shown in FIG. 1, a portable digital data storage device 11 is electrically connected with an external electronic device 13 through a communication interface 12 so as to exchange data with the external electronic device 13. The external electronic device 13 is for example a computer or any other data processing device. The portable digital data storage device 11 comprises a control unit 111, a storage unit 113, a display unit 115 and a power supply unit 117. Optionally, the control unit 111 of the portable digital data storage device 11 may be collaboratively used with the external electronic device 13. Alternatively, the control unit 111 of the portable digital data storage device 11 is only configured to control the storage unit 113, the display unit 115 and the power supply unit 117.

In a case that the control unit 111 of the portable digital data storage device 11 is collaboratively used the external electronic device 13, the control unit 111 may receive the command from the external electronic device 13. In response to the command, the control unit 111 controls an accessing operation of the storage unit 113. An example of the communication interface 12 includes a universal serial bus (USB) interface, an IEEE 1394 interface, an integrated device electronics (IDE) interface, a serial advanced technology attachment (SATA), or a combination thereof. The external electronic device 13 is for example a computer or a data processing device with high computing capability.

Therefore, the present invention can be applied to any portable digital data storage devices 11 having embedded file systems, wherein the file systems provide information regarding the storage space of the portable digital data storage devices 11. Besides, the types of the communication interface 12 used for connecting the portable digital data storage devices 11 external electronic devices are not limited to the ones enumerated above.

Please refer to FIG. 1 again. The main components of the portable digital data storage device 11 comprise the storage unit 113 and the control unit 111. The control unit 111 is electrically connected with the communication interface 12.

The storage unit 113 has a storage space for storing data. The storage space of the storage unit 113 may be divided into a plurality of storage blocks. According to the practical requirements, each of storage blocks has a storage capacity of 512 bytes, 1024 bytes, 2048 bytes, 4096 bytes, and so on.

As mentioned above, the storage space of the storage unit 113 may be divided into a plurality of storage blocks for storing data. Moreover, in accordance with a key feature of the present invention, the storage space of the storage unit 113 may be divided into a plurality of analyzable sections. In addition to the function of controlling the accessing operation of the storage unit 113, the control unit 113 may judge the utilization condition of the storage space according to the usage statuses of respective analyzable sections, thereby acquiring the analyzing information of the storage space.

In addition to the storage unit and the control unit, the portable digital data storage device 11 further comprises the display unit 15. The display unit 15 is electrically connected with the control unit 13. The display unit 15 is configured to store associated information of the storage unit 11 and the analyzing result of the storage space. An example of the display unit 15 includes but is not limited to a bi-stable display (e.g. a cholesteric liquid crystal display, a ferroelectric liquid crystal display, an electrophoretic display, a MEMS-switchable reflector display or an electrochromic display), or LED indicator. For example, the LED indicator may comprise a plurality of LED lamps, wherein different number of LED lamps are turned on to indicate the residual storage space.

Since the portable digital data storage device 11 has the built-in display unit, the user may easily and directly realize the analyzing result of the storage space by reading the operating messages and associated information of the display unit without the need of connecting the portable digital data storage device 11 to the external electronic device. That is, by using the display unit to show the associated information of the storage unit, the convenience of the portable digital data storage device 11 is enhanced.

Moreover, the portable digital data storage device 11 further comprises a power supply unit 17 for providing electricity required to analyze the storage space of the portable digital data storage device 11 and/or refreshing the display unit 115. That is, the use of the power supply unit 117 may facilitate the portable digital data storage device 11 to acquire the associated information of the storage space and increase the flexibility of displaying the associated information.

In this embodiment, the control unit 111 comprises a sampling module 1113 and an analyzing module 1111. The sampling module 1113 and the analyzing module 1111 are electrically connected with each other. The sampling module 1113 is used for acquiring the usage statuses of respective analyzable sections. After the usage statuses of respective analyzable sections are acquired, the analyzing module 1111 will classify the usage statuses of respective analyzable sections. After the usage statuses of respective analyzable sections are classified, the counts of the analyzable sections with the same logic state are accumulated as an accumulation value, and the accumulation value is multiplied by the number (N) of bits of each analyzable section to obtain the analyzing information of the storage space, wherein N is a positive integer.

In addition to the function of analyzing the utilization condition of the storage space, the analyzing module 1111 is able to analyze the file system format and the associated information of the storage unit.

Take the function of analyzing the file system format for example. The analyzing module 1111 may analyze various types of file systems. For example, the analyzing module 1111 may judge which file system format is used in the storage unit 113. The file system format includes for example a file allocation table (FAT), a file allocation table 32 (FAT32), an extended file allocation table (exFAT), a new technology file system (NTFS), a hierarchical file system (HFS), a hierarchical file system + (HFS+), a second extended file system (EXT2), a third extended file system (EXT3), a fourth extended file system (EXT4), or an X file system (XFS) etc. Of course, if different storage blocks of the storage unit 113 use different file system formats, the analyzing module 1111 may support and judge corresponding file system formats.

Take the function of analyzing the information of the storage unit for example. After the file system format is analyzed and realized, associated information of the storage unit will be analyzed. For example, the control unit 111 may further judge whether the storage space of the storage unit 113 is greater than 2 terabytes (TB), thereby supporting the storage space greater than 2TB.

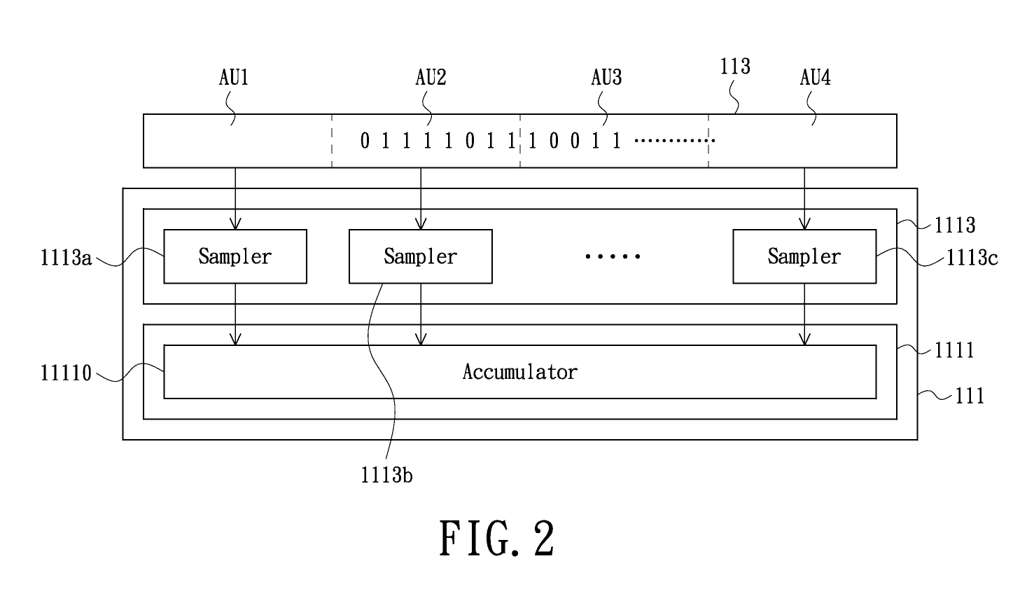

Please refer to FIG. 2, which schematically illustrates the relationship between the storage unit and the samplers and the accumulator of the control unit. The storage space of the storage unit 113 is divided into a plurality of analyzable sections AU1˜AU4. Each of the analyzable sections AU1˜AU4 comprises N bits, wherein N is a positive integer. That is, the analyzable section comprises at least one bit. For clarification and brevity, only four analyzable sections are shown in FIG. 2. In practice, the number and size of the analyzable sections are not restricted. For example, each of the analyzable sections may include 2, 4, 8, 16, 32 or 64 bits.

Moreover, the sizes of the analyzable sections and the storage blocks of the storage space, and the relation between the analyzable sections and the storage blocks of the storage space are not restricted. For example, each storage block may contain 256 analyzable sections or 128 analyzable sections.

The utilization conditions of the analyzable sections AU1˜AU4 may be analyzed according to the logic statuses of the analyzable sections AU1˜AU4. For example, since the logic states of all bits of the analyzable section AU1 are “0”, the logic state of the analyzable section AU1 is expressed as “0” to indicate that the analyzable section AU1 is unused. Whereas, since each of the analyzable sections AU2˜AU4 includes at least one whose logic state is “1”, the logic states of the analyzable sections AU2˜AU4 are expressed as “1” to indicate that at least one bit has been stored in each of the analyzable sections AU2˜AU4.

Then, the counts of the analyzable sections with the same logic state are accumulated to estimate the utilization condition of the storage space of the storage unit. For example, after the counts of the analyzable sections having the logic state “1” are accumulated as an accumulation value, the accumulation value is multiplied by the number (N) of bits of each analyzable section to estimate the used storage space of the storage unit 113. On the other hand, after the counts of the analyzable sections having the logic state “0” are accumulated as an accumulation value, the accumulation value is multiplied by the number (N) of bits of each analyzable section to estimate the usable storage space of the storage unit 113.

For quickly analyzing the utilization condition of the storage space, each analyzable section AU comprises a plurality of bits. For example, each analyzable section AU comprises 2, 4, 8, 16, 32 or 64 bits. Then, the utilization conditions of the analyzable sections AU1˜AU4 are analyzed according to the logic statuses of the analyzable sections AU1˜AU4. For example, since the logic states of all bits of the analyzable section AU1 are “0”, the logic state of the analyzable section AU1 is expressed as “0” to indicate that the analyzable section AU1 is unused. Whereas, since each of the analyzable sections AU2˜AU4 includes at least one whose logic state is “1”, the logic states of the analyzable sections AU2˜AU4 are expressed as “1” to indicate that at least one bit has been stored in each of the analyzable sections AU2˜AU4.

As mentioned above, the process of acquiring the logic states of the respective analyzable sections and the subsequent process of accumulating the counts of the respective logic states and analyzing the storage space can be implemented by software or hardware. For example, the hardware components include a plurality of samplers and an accumulator.

Please refer to FIG. 2 again. The sampling module 1113 comprises a plurality of samplers 1113a˜1113c. The analyzing module 1111 comprises an accumulator 11110. The samplers 1113a˜1113c are electrically connected with the accumulator 11110. After the logic states corresponding to the analyzable sections are acquired by these samplers 1113a˜1113c in parallel, a plurality of data bits representing the logic states will be acquired.

Then, the data bits with the same logic state are acquired by the samplers 1113a˜1113c and accumulated by the accumulator 11110. According to the accumulating result, the control unit 111 may analyze the utilization condition of the storage space. For example, if the data bits of the analyzable sections having the logic state “1” is accumulated as an accumulation value and the accumulation value is multiplied by the number (N) of bits of each analyzable section, the used storage space of the storage unit 113 will be estimated. On the other hand, if the data bits of the analyzable sections having the logic state “0” is accumulated as an accumulation value and the accumulation value is multiplied by the number (N) of bits of each analyzable section, the usable storage space of the storage unit 113 will be estimated.

In an embodiment, the counts of the analyzable sections are successively accumulated by the accumulator 11110 by software. In some embodiments, the logic states corresponding to the usage statuses of the analyzable sections are acquired by the samplers of the sampling module 1113 by hardware. In such manner, the logic states corresponding to the analyzable sections are acquired by these samplers in parallel and simultaneously accumulated, so that the analyzing time is largely shortened. In other words, the approach of acquiring the analyzing information is not limited to software or hardware. Since the storage space can be effectively estimated by the analyzing method of the present invention, the computing amount is reduced. Even if the processing unit has inferior computing capacity and the analyzing method is performed by software, it is time-saving to analyze the utilization condition of the storage space of the portable digital data storage device.

In some embodiments, for enhancing the accuracy of the analyzing result, the number of bits of the analyzable section may be reduced. For example, in comparison with the result of analyzing the space storage whose analyzable section has eight bits, the result of analyzing the space storage whose analyzable section has two bits has higher accuracy. Of course, if each analyzable section has one bit, the estimated used storage space and the estimated usable storage space are equal to the actual used storage space and the actual usable storage space, respectively.

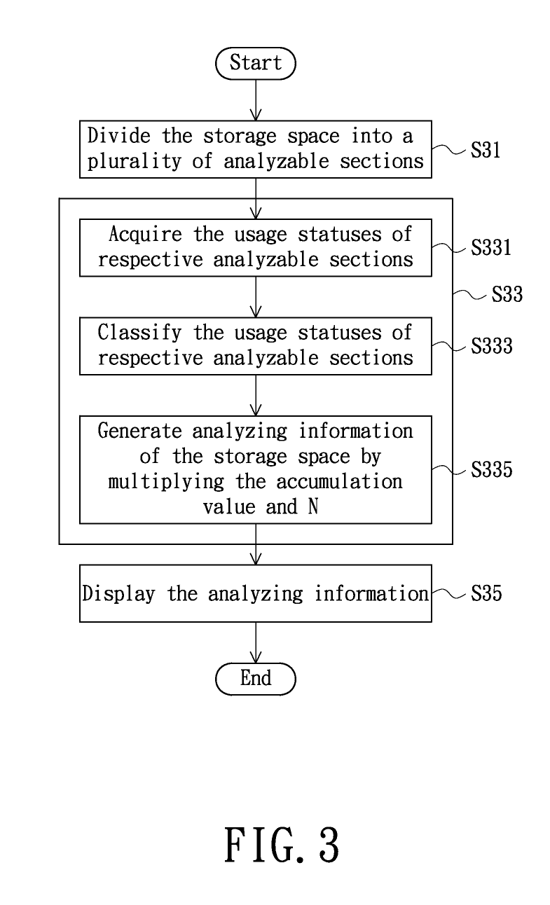

FIG. 3 is a flowchart illustrating an analyzing method for analyzing a storage space of a portable digital data storage device according to an embodiment of the present invention. The analyzing method comprises the following steps. Firstly, the storage space is divided into a plurality of analyzable sections (Step S31). Then, a utilization condition of the storage space is judged according to the usage statuses of respective analyzable sections, so that the analyzing information of the storage space is acquired (Step S33). After the analyzing information is acquired, the analyzing information is transmitted to the external electronic device or displayed on the display unit (Step S35).

The step S33 may further comprises the sub-steps S331, S333 and S335. In the sub-step S331, the usage statuses of respective analyzable sections are acquired. In the sub-step S333, the usage statuses of respective analyzable sections are classified. After the usage statuses of respective analyzable sections are classified, the counts of the analyzable sections with the same logic state are accumulated as an accumulation value, and the accumulation value is multiplied by the number (N) of bits of each analyzable section to obtain the analyzing information of the storage space (in the sub-step S335).

In the above embodiment, the method of analyzing the storage space of the storage unit includes the following steps. Firstly, the storage space is divided into a plurality of analyzable sections. The usage status of each analyzable section is expressed by a logic state. Then, a plurality of data bits are acquired in parallel by a plurality of samplers. The counts of the analyzable sections with the same logic state are accumulated to estimate the utilization condition of the storage space of the storage unit. Since the storage space can be effectively estimated in a parallel processing manner, the computing amount is reduced. Even if the processing unit has inferior computing capacity and the analyzing method is performed by software, it is time-saving to analyze the utilization condition of the storage space of the portable digital data storage device.

From the above description, the analyzing method of the present invention is capable of quickly acquiring the analyzing information of the storage unit of the portable digital data storage device. Since the computing amount is largely reduced, the time period of analyzing the utilization condition of the storage space is shortened. Under this circumstance, the processing unit of the portable digital data storage device may be simplified. Moreover, associated information of the portable digital data storage device can be easily acquired without the need of connecting with the external electronic device.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A portable digital data storage device selectively in communication with an external electronic device through a communication interface, the portable digital data storage device comprising:
a storage unit having a storage space, wherein the storage space is divided into a plurality of analyzable sections; and
a control unit electrically connected with the communication interface for controlling an accessing operation of the storage unit, wherein the control unit judges a utilization condition of the storage space according to usage statuses of respective analyzable sections, thereby acquiring analyzing information of the storage space.

2. The portable digital data storage device according to claim 1, wherein control unit further judges whether the storage space of the storage unit is greater than 2 terabytes.

3. The portable digital data storage device according to claim 1, wherein the control unit comprises:
a sampling module for acquiring the usage statuses of respective analyzable sections; and
an analyzing module electrically connected with the sampling module for classifying the usage statuses of respective analyzable sections, thereby acquiring the analyzing information of the storage space.

4. The portable digital data storage device according to claim 3, wherein each of the analyzable sections contains N bits, wherein N is a positive integer, wherein the counts of the analyzable sections with the same logic state are accumulated as an accumulation value, and the accumulation value is multiplied by N to obtain the analyzing information of the storage space.

5. The portable digital data storage device according to claim 1, wherein the portable digital data storage device is a non-volatile storage device, wherein the non-volatile storage device is a hard disc or a flash memory.

6. The portable digital data storage device according to claim 1, further comprising a display unit, which is electrically connected with the control unit for displaying the analyzing information.

7. The portable digital data storage device according to claim 6, wherein the display unit is a bi-stable display, a LED indicator, a cholesteric liquid crystal display, a ferroelectric liquid crystal display, an electrophoretic display, a MEMS-switchable reflector display or an electrochromic display.

8. The portable digital data storage device according to claim 1, wherein the analyzing information comprises a film system format, a used storage space, a usable storage space or a volume label.

9. The portable digital data storage device according to claim 8, wherein the file system format includes a file allocation table (FAT), a file allocation table 32 (FAT32), an extended file allocation table (exFAT), a new technology file system (NTFS), a hierarchical file system (HFS), a hierarchical file system + (HFS+), a second extended file system (EXT2), a third extended file system (EXT3), a fourth extended file system (EXT4), or an X file system (XFS).

10. The portable digital data storage device according to claim 1, wherein the communication interface is a universal serial bus (USB) interface, an IEEE 1394 interface, an integrated device electronics (IDE) interface or a serial advanced technology attachment (SATA).

11. The portable digital data storage device according to claim 1, further comprising a power supply unit, which is electrically connected with the control unit for providing electricity to the control unit to control the accessing operation of the storage unit.

12. An analyzing method for analyzing a storage space of a portable digital data storage device, the analyzing method comprising steps of:
(a) dividing the storage space into a plurality of analyzable sections; and
(b) judging a utilization condition of the storage space according to usage statuses of respective analyzable sections, thereby acquiring analyzing information of the storage space.

13. The analyzing method according to claim 12, wherein the step (b) comprises sub-steps of:
(b1) acquiring the usage statuses of respective analyzable sections;
(b2) classifying the usage statuses of respective analyzable sections; and
(b3) accumulating the counts of the analyzable sections with the same logic state as an accumulation value, and acquiring the analyzing information according to the accumulation value and the number of bits contained in each of the analyzable sections, wherein each of the analyzable sections contains N bits, wherein N is a positive integer.

14. The analyzing method according to claim 13, wherein in the step (b3), the accumulation value is multiplied by N to obtain the analyzing information of the storage space.

15. The analyzing method according to claim 12, wherein the portable digital data storage device is a non-volatile storage device, wherein the non-volatile storage device is a hard disc or a flash memory.

16. The analyzing method according to claim 12, further comprising a step of providing a display unit for displaying the analyzing information.

17. The analyzing method according to claim 16, wherein the display unit is a bi-stable display, a LED indicator, a cholesteric liquid crystal display, a ferroelectric liquid crystal display, an electrophoretic display, a MEMS-switchable reflector display or an electrochromic display.

18. The analyzing method according to claim 12, wherein the analyzing information comprises a film system format, a used storage space, a usable storage space or a volume label.

19. The analyzing method according to claim 18, wherein the file system format includes a file allocation table (FAT), a file allocation table 32 (FAT32), an extended file allocation table (exFAT), a new technology file system (NTFS), a hierarchical file system (HFS), a hierarchical file system + (HFS+), a second extended file system (EXT2), a third extended file system (EXT3), a fourth extended file system (EXT4).

20. The analyzing method according to claim 12, wherein the analyzing information is transmitted to an external electronic device through a communication interface, wherein the communication interface is a universal serial bus (USB) interface, an IEEE 1394 interface, an integrated device electronics (IDE) interface or a serial advanced technology attachment (SATA).
